(19) United States
(12) Patent Application Publication
(10) Pub. No.: US 2025/0338400 A1
(43) Pub. Date: Oct. 30, 2025

(54) TRANSDUCER CIRCUIT BOARD AND METHOD OF MANUFACTURING THE SAME

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (CN)

(72) Inventor: Jun DAI, Hebei Province (CN)

(21) Appl. No.: 18/645,131

(22) Filed: Apr. 24, 2024

(51) Int. Cl. H05K 1/11; H04N 23/54; H04N 23/68; H05K 1/02; H05K 3/36

(52) U.S. Cl. CPC H05K 1/112; H05K 1/0213; H05K 3/36; H04N 23/54; H04N 23/687

(57) ABSTRACT

A transducer circuit board includes a movable circuit board unit, a fixed circuit board unit, suspensions and an actuator circuit board unit. The movable circuit board unit includes a main body and cantilevers extending from the main body. The fixed circuit board unit is disposed outside the movable circuit board unit and has a first side, a second side, a third side, and a fourth side. The suspensions are disposed between the movable circuit board unit and the fixed circuit board unit, and each suspension connects to the movable circuit board unit and the fixed circuit board unit. The actuator circuit board unit is electrically connected to the fixed circuit board unit, and includes an X-axis coil disposed at the first side, a Y-axis coil disposed at the third side, and a Z-axis coil disposed at the fourth side.

### BACKGROUND

### Field of Invention

The present disclosure relates to a circuit board. More particularly, the present disclosure relates to a transducer circuit board and a method of manufacturing the same.

### Description of Related Art

In order to improve the stability of the camera lens, a transducer stabilization module is now available that uses a voice coil motor as the power to move the transducer. However, transducer stabilization modules using voice coil motors are not easy to package for small-sized electronic devices such as mobile phones. Therefore, most of the transducer stabilization modules using voice coil motors only have plane physical anti-shaking of the X-axis and Y-axis, while the other axes are compensated by software methods, such as image processing, to achieve the image anti-shaking effect.

### SUMMARY

At least one embodiment of the present disclosure provides a transducer circuit board and a method of manufacturing the same, thereby solving the problem of difficulty in packaging design of a multi-axial transducer stabilization module.

The transducer circuit board according to at least one embodiment of the present disclosure includes a movable circuit board unit, a fixed circuit board unit, a plurality of suspensions, and an actuator circuit board unit. The movable circuit board unit includes a main body and a plurality of cantilevers extending from the main body. The fixed circuit board unit is disposed outside the movable circuit board unit and has a first side, a second side opposite to the first side, a third side between the first side and the second side, and a fourth side opposite to the third side. The suspensions are disposed between the movable circuit board unit and the fixed circuit board unit, where each of the suspensions connects to the movable circuit board unit and the fixed circuit board unit. The actuator circuit board unit is electrically connected to the fixed circuit board unit and includes a first X-axis coil disposed at the first side, a Y-axis coil disposed at the third side, and a first Z-axis coil disposed at the fourth side.

The method of manufacturing the transducer circuit board according to at least one embodiment of the present disclosure includes the following steps. A substrate is provided. A first conductive via in the substrate is formed. The substrate is patterned. A plurality of metal layers are adhered to a top surface and a bottom surface of the substrate with a plurality of insulating mediums respectively after the substrate is patterned. A plurality of second conductive vias in the metal layers and the insulating mediums located on the top surface and the bottom surface of the substrate are formed. The metal layers located on the top surface and the bottom surface of the substrate are patterned. A plurality of protective films on the metal layers located on the top surface and the bottom surface of the substrate are formed respectively after the metal layers located on the top surface and the bottom surface of the substrate are patterned. The insulating mediums located on the top surface and the bottom surface of the substrate and a base layer of the substrate are cut.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic top view of a transducer circuit board according to at least one embodiment of the present disclosure.

FIG. 2 is a schematic cross-sectional view taken along line A-A′ in FIG. 1.

FIG. 3 is a schematic diagram of a use state of a transducer circuit board according to at least one embodiment of the present disclosure.

FIG. 4A is a schematic top view of a fixed circuit board unit according to at least one embodiment of the present disclosure.

FIG. 4B is a schematic cross-sectional view taken along line B-B′ in FIG. 4A.

FIGS. 5A to 5G are schematic cross-sectional views of a method of manufacturing the transducer circuit board in FIG. 2.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

The spatial relative terms used in the present disclosure, such as “below,” “under,” “above,” “on,” and the like, are intended to facilitate the recitation of a relative relationship between one element or feature and another as depicted in the figures. The true meaning of these spatial relative terms includes other orientations. For example, the relationship between one element and another may change from “below” and “under” to “above” and “on” when the figure is turned 180 degrees up or down. In addition, spatially relative descriptions used in the present disclosure should be interpreted in the same manner.

It should be understood that while the present disclosure may use terms such as “first”, “second”, “third”, etc. to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Although a series of operations or steps are used to illustrate the manufacturing method in the present disclosure, the order shown in these operations or steps should not be construed as a limitation of the present disclosure. For example, some operations or steps may be performed in a different order and/or concurrently with other steps. In addition, each operation or step described herein may include several sub-steps or actions.

Moreover, the present disclosure may be implemented or applied in various other specific embodiments, and the details of the present disclosure may be combined, modified, and altered in various embodiments based on different viewpoints and applications, without departing from the idea of the present disclosure.

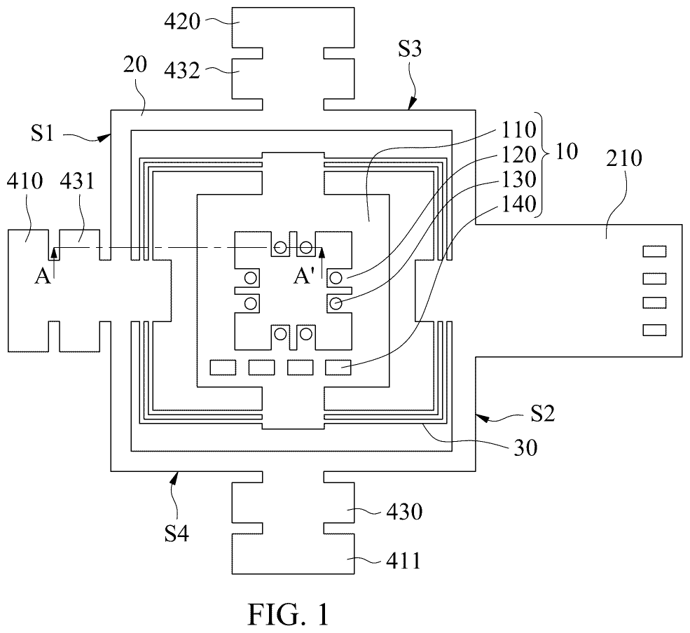

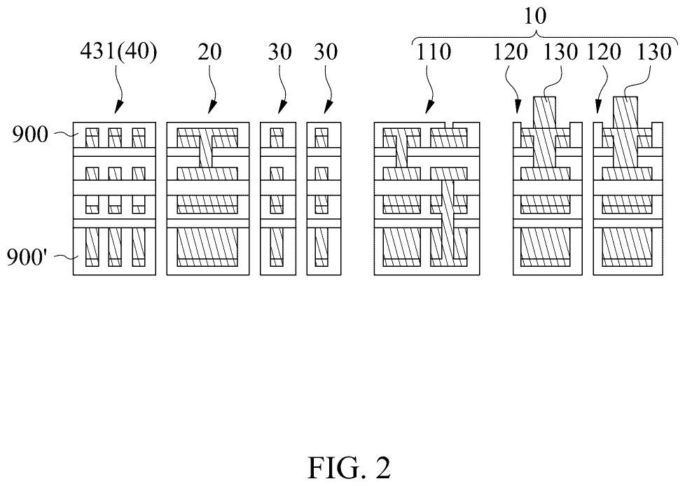

FIG. 1 is a schematic top view of a transducer circuit board according to at least one embodiment of the present disclosure. FIG. 2 is a schematic cross-sectional view taken along line A-A′ in FIG. 1. Referring to FIG. 1 and FIG. 2, the transducer circuit board 1 includes a movable circuit board unit 10, a fixed circuit board unit 20, a plurality of suspensions 30, and an actuator circuit board unit 40.

The movable circuit board unit 10 includes a main body 110 and a plurality of cantilevers 120 extending from the main body 110. The fixed circuit board unit 20 is disposed outside the movable circuit board unit 10 and surrounds the movable circuit board unit 10. The fixed circuit board unit 20 has a first side S1, a second side S2 opposite to the first side S1, a third side S3 located between the first side S1 and the second side S2, and a fourth side S4 opposite to the third side S3.

The suspensions 30 are disposed between the movable circuit board unit 10 and the fixed circuit board unit 20, where the suspensions 30 are disposed around the movable circuit board unit 10. The fixed circuit board unit 20 surrounds the suspensions 30. Each of the suspensions 30 connects to the movable circuit board unit 10 and the fixed circuit board unit 20. The actuator circuit board unit 40 is electrically connected to the fixed circuit board unit 20 and includes a first X-axis coil 410, a Y-axis coil 420, and a first Z-axis coil 430. The first X-axis coil 410 is disposed at the first side S1, the Y-axis coil 420 is disposed at the third side S3, and the first Z-axis coil 430 is disposed at the fourth side S4.

With the above package design of the transducer circuit board, the X-axis coil, Y-axis coil and Z-axis coil of the voice coil motor can be integrated into the transducer circuit board, thus solving the problem of difficulty in packaging design of a multi-axial transducer stabilization module to achieve the multi-axis physical anti-shaking effect.

Referring to FIG. 1, the movable circuit board unit 10 further includes a plurality of transducer connection pads 130 and a plurality of electronic components 140, where the transducer connection pads 130 are disposed on the cantilevers 120 respectively, and the electronic components 140 are disposed on the main body 110. The fixed circuit board unit 20 further includes a connection part 210 extending from the second side S2 and electrically connected to an external circuit. In some embodiments, each of the transducer connection pads 130 may include a copper pillar. The electronic components 140 may include a resistor, an inductor, a capacitor, or a combination thereof.

The actuator circuit board unit 40 further includes a second X-axis coil 411, a second Z-axis coil 431, and a third Z-axis coil 432. The second X-axis coil 411 is disposed at the fourth side S4, the second Z-axis coil 431 is disposed at the first side S1, and the third Z-axis coil 432 is disposed at the third side S3.

In some embodiments, the first X-axis coil 410, the second X-axis coil 411, the Y-axis coil 420, the first Z-axis coil 430, the second Z-axis coil 431, and the third Z-axis coil 432 may be formed in the fixed circuit board unit 20 by etching or plating. In other embodiments, the aforementioned coils may also be connected to the fixed circuit board unit 20 by an external connection, such as surface mount technology (SMT) or hot bar soldering.

In addition, as shown in FIG. 1, the suspensions 30 are disposed at four corners of the fixed circuit board unit 20. For example, the suspensions 30 are disposed at the corner between the first side S1 and the third side S3, the corner between the third side S3 and the second side S2, the corner between the second side S2 and the fourth side S4, and the corner between the fourth side S4 and the first side S1, respectively. The cantilevers 120 may be disposed at four sides or four corners of the movable circuit board unit 10. For example, the cantilevers 120 are respectively disposed at the sides of the movable circuit board unit 10 parallel to the first side S1, the second side S2, the third side S3, and the fourth side S4, respectively.

In some embodiments, the suspensions 30 and the cantilevers 120 may include supportive and resilient members such as a wire, a spring, or a combination thereof. The material of the suspensions 30 and the cantilevers 120 may include titanium-copper alloy, copper-nickel alloy, carbon steel or a combination thereof, to provide better support and resilience.

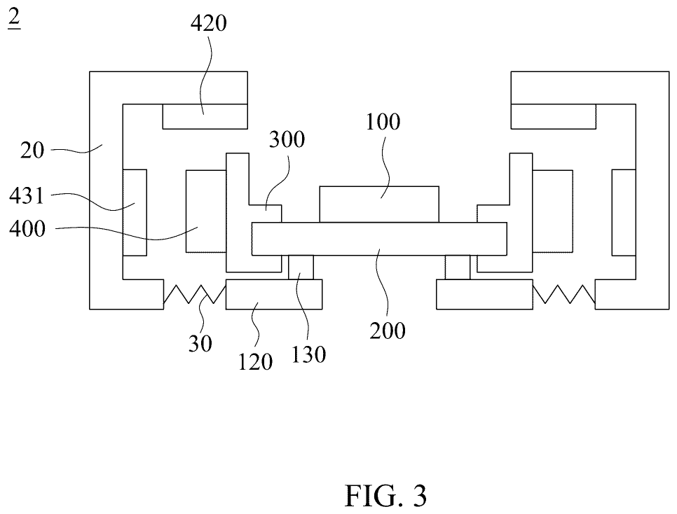

FIG. 3 is a schematic diagram of a use state of a transducer circuit board according to at least one embodiment of the present disclosure. Referring to FIG. 1 and FIG. 3, in a camera lens 2, an image transducer 100 is disposed on a base 200 and is welded to the transducer connection pads 130 by the base 200. A fixing frame 300 fixes the base 200, and a permanent magnet 400 is disposed on the fixing frame 300.

The Lorentz force generated between the permanent magnet 400 and the coils (e.g., Y-axis coil 420 and Z-axis coil 431) with electricity is utilized to control the stretching and bending of the suspensions 30 and the cantilevers 120 to move the image transducer 100 to the proper position for capturing a clear image.

Specifically, the direction and the magnitude of the amperage force can be changed by controlling the direction and the magnitude of the current in the coils, thus enabling the image transducer 100 to move in different directions. For example, the first X-axis coil 410, the second X-axis coil 411, and the Y-axis coil 420 can move the image transducer 100 left and right, and the first Z-axis coil 430, the second Z-axis coil 431, and the third Z-axis coil 432 can move the image transducer 100 tilting so that multi-axis physical anti-shake effect can be achieved. Furthermore, the first Z-axis coil 430, the second Z-axis coil 431 and the third Z-axis coil 432 can also move the image transducer 100 up and down so that auto-focus effect can be achieved.

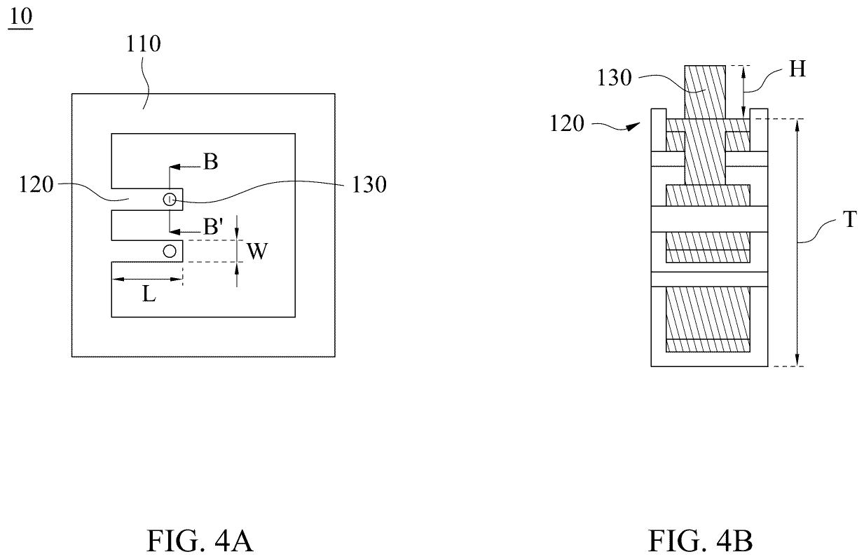

FIG. 4A is a schematic top view of a fixed circuit board unit according to at least one embodiment of the present disclosure. FIG. 4B is a schematic cross-sectional view taken along line B-B′ in FIG. 4A. Referring to FIG. 4A and FIG. 4B, in order to simplify the expression of the figure, FIG. 4A merely shows two cantilevers 120 as a representative representation. However, it is understood that other cantilevers 120 may also be included but not shown in the figure.

As shown in FIG. 4A and FIG. 4B, the cantilever 120 has a length L, a width W, and a thickness T, and the transducer connection pad 130 disposed on the cantilever 120 has a height H. By adjusting the length L, the width W, the thickness T, and the elastic modulus of material of each layer of the cantilever 120, the bending stress of the cantilever 120 can be varied, so as to design the specifications for the above-mentioned coils and the permanent magnets. The height H of the transducer connection pad 130 primarily affects the displacement compensation angle of the transducer in the height direction (i.e., the Z-axis), with the greater the height H, the greater the displacement compensation angle, which is typically designed to be greater than 1 degree. Furthermore, the shape of the cantilever 120 may be a rectangle, a serpentine line, or a spiral line, or other suitable shape.

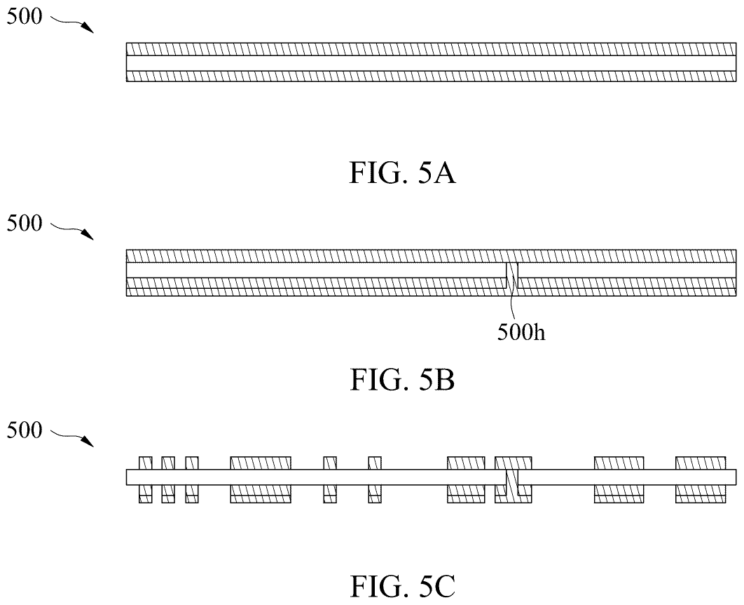

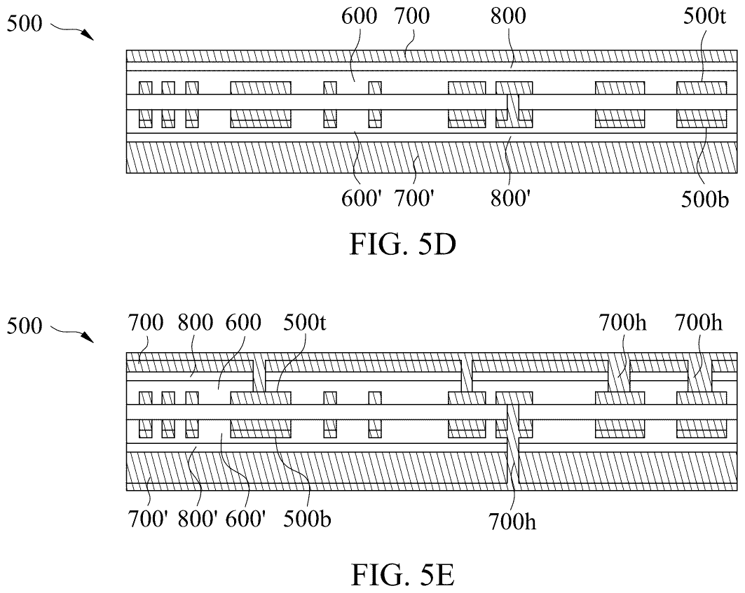

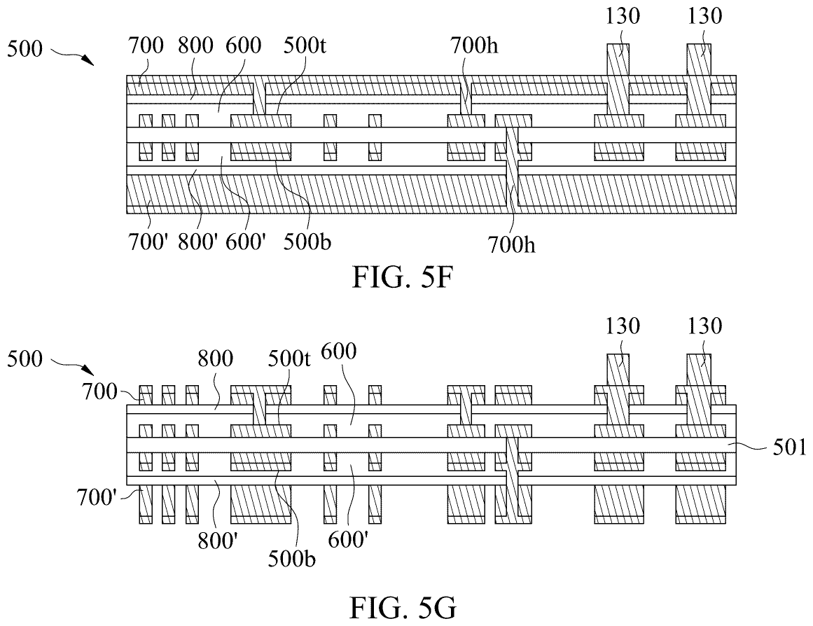

FIGS. 5A to 5G are schematic cross-sectional views of a method of manufacturing the transducer circuit board in FIG. 2. Referring to FIG. 5A to FIG. 5G and FIG. 2, first, as shown in FIG. 5A, a substrate 500 is provided. Then, as shown in FIG. 5B, a first conductive via 500h is formed in the substrate 500. Next, as shown in FIG. 5C, the substrate 500 is patterned, that is, the substrate 500 is patterned by photolithography.

Next, as shown in FIG. 5D, after the substrate 500 is patterned, a plurality of metal layers 700, 700′ are respectively adhered to the top surface 500t and the bottom surface 500b of the substrate 500 with a plurality of insulating mediums 600, 600′, where a plurality of intermediate layers 800, 800′ may be disposed between the metal layers 700, 700′ and the insulating mediums 600, 600′.

Then, as shown in FIG. 5E, a plurality of second conductive vias 700h are formed in the insulating mediums 600, 600′ and the metal layers 700, 700′ located on the top surface 500t and the bottom surface 500b of the substrate 500.

Next, as shown in FIG. 5F and FIG. 5G, the metal layers 700 and 700′ located on the top surface 500t and the bottom surface 500b of the substrate 500 are patterned. In some embodiments, before patterning the metal layers 700, 700′, a plurality of transducer connection pads 130 may be formed on the metal layer 700 located on the top surface 500t of the substrate 500.

Then, as shown in FIG. 2, after the metal layers 700, 700′ located on the top surface 500t and the bottom surface 500b of the substrate 500 are patterned, a plurality of protective films 900, 900′ are respectively formed on the metal layers 700, 700′ located on the top surface 500t and the bottom surface 500b of the substrate 500, and the insulating mediums 600, 600′ and a base layer 501 of the substrate 500 are cut to form a movable circuit board unit 10, a fixed circuit board unit 20, a plurality of suspensions 30 and a actuator circuit board unit 40.

In some embodiments, the material of the insulating mediums 600, 600′ may include poly (methyl methacrylate) (PMMA), epoxy resin or polypropylene resin. The material of the intermediate layers 800, 800′ may include polyimide (PI). The protective films 900, 900′ can be solder masks, and the material of the solder masks may include ink, etc.

In summary, in the abovementioned transducer circuit board and its manufacturing method in at least one embodiment of the present disclosure, with the above package design of the transducer circuit board, the X-axis coil, Y-axis coil and Z-axis coil of the voice coil motor can be integrated into the transducer circuit board, thus solving the problem of difficulty in packaging design of a multi-axial transducer stabilization module to achieve the multi-axis physical anti-shaking effect.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A transducer circuit board, comprising:
a movable circuit board unit, comprising a main body and a plurality of cantilevers extending from the main body;
a fixed circuit board unit, disposed outside the movable circuit board unit and having a first side, a second side opposite to the first side, a third side between the first side and the second side, and a fourth side opposite to the third side;
a plurality of suspensions, disposed between the movable circuit board unit and the fixed circuit board unit, wherein each of the suspensions connects to the movable circuit board unit and the fixed circuit board unit; and
an actuator circuit board unit, electrically connected to the fixed circuit board unit, and comprises:
a first X-axis coil, disposed at the first side;
a Y-axis coil, disposed at the third side; and
a first Z-axis coil, disposed at the fourth side.

2. The transducer circuit board of claim 1, wherein the movable circuit board unit further comprises a plurality of transducer connection pads disposed on the cantilevers respectively.

3. The transducer circuit board of claim 2, wherein each of the transducer connection pads comprises a copper pillar.

4. The transducer circuit board of claim 1, wherein the fixed circuit board unit further comprises a connection part extending from the second side.

5. The transducer circuit board of claim 1, wherein each of the suspensions comprises a suspension wire.

6. The transducer circuit board of claim 1, wherein the movable circuit board unit further comprises a plurality of electronic components disposed on the main body.

7. The transducer circuit board of claim 6, wherein the electronic components comprise a resistor, an inductor, a capacitor, or a combination thereof.

8. The transducer circuit board of claim 1, wherein the actuator circuit board unit further comprises a second X-axis coil disposed at the fourth side.

9. The transducer circuit board of claim 1, wherein the actuator circuit board unit further comprises a second Z-axis coil disposed at the first side.

10. The transducer circuit board of claim 9, wherein the actuator circuit board unit further comprises a third Z-axis coil disposed at the third side.

11. The transducer circuit board of claim 1, wherein the suspensions are respectively disposed at a corner between the first side and the third side, a corner between the third side and the second side, a corner between the second side and the fourth side, and a corner between the fourth side and the first side.

12. The transducer circuit board of claim 1, wherein the cantilevers are respectively disposed at a side of the movable circuit board unit parallel to the first side, a side of the movable circuit board unit parallel to the second side, a side of the movable circuit board unit parallel to the third side, and a side of the movable circuit board unit parallel to the fourth side.

13. The transducer circuit board of claim 1, wherein materials of the suspensions and the cantilevers comprise titanium-copper alloy, copper-nickel alloy, carbon steel or a combination thereof.

14. A method of manufacturing a transducer circuit board, comprising:
providing a substrate;
forming a first conductive via in the substrate;
patterning the substrate;
making a plurality of metal layers adhere to a top surface and a bottom surface of the substrate with a plurality of insulating mediums respectively after the substrate is patterned;
forming a plurality of second conductive vias in the metal layers and the insulating mediums located on the top surface and the bottom surface of the substrate;
patterning the metal layers located on the top surface and the bottom surface of the substrate;
forming a plurality of protective films on the metal layers located on the top surface and the bottom surface of the substrate respectively after the metal layers located on the top surface and the bottom surface of the substrate are patterned; and
cutting the insulating mediums located on the top surface and the bottom surface of the substrate and a base layer of the substrate.

15. The method of manufacturing the transducer circuit board of claim 14, further comprises forming a plurality of transducer connection pads on the metal layer located on the top surface of the substrate before the metal layers are patterned.
